(19) United States
(12) Patent Application Publication
(10) Pub. No.: US 2023/0343891 A1
(43) Pub. Date: Oct. 26, 2023

(54) MASS TRANSFER SYSTEM AND MASS TRANSFER METHOD

(71) Applicant: Tianma Advanced Display Technology Institute (Xiamen) Co., Ltd., Xiamen (CN)

(72) Inventor: Peixuan CHEN, Xiamen (CN)

(73) Assignee: Tianma Advanced Display Technology Institute (Xiamen) Co., Ltd., Xiamen (CN)

(21) Appl. No.: 18/217,345

(22) Filed: Jun. 30, 2023

(30) Foreign Application Priority Data
Mar. 31, 2023 (CN) 202310341675.1

(51) Int. Cl. H01L 33/38; H01L 21/683; H01L 33/00

(52) U.S. Cl. CPC H01L 33/0093; H01L 21/6835; H01L 33/385; H01L 2221/68368; H01L 2933/0016

(57) ABSTRACT

A mass transfer system and a mass transfer method are provided. The mass transfer system is used for transferring micro light-emitting diodes (microLEDs) to an array substrate. The mass transfer system includes a transfer device and a calibration device. The transfer device is configured to absorb multiple microLEDs and transfer the multiple microLEDs to the calibration device. The calibration device includes multiple calibration points. One of the multiple calibration points is configured to absorb one of the multiple microLEDs and perform position calibration on the one of the multiple microLEDs. The calibration device is also configured to transfer the multiple microLEDs to the array substrate through electrical control.

### CROSS-REFERENCE TO RELATED APPLICATION(S)

This application claims priority to Chinese Patent Application No. 202310341675.1 filed Mar. 31, 2023, the disclosure of which is incorporated herein by reference in its entirety.

### TECHNICAL FIELD

The present disclosure relates to the field of display technologies and, in particular, to a mass transfer system and a mass transfer method.

### BACKGROUND

A micro light-emitting diode (microLED) has the characteristic of self-illumination. Compared with an organic light-emitting diode (OLED) and a liquid crystal display (LCD), the microLED display is featured with relatively easy and accurate color adjustment, a longer emission lifetime, higher brightness, and higher resolution, is thinner, lighter, and more power-saving, and has great development potential in the field of display technologies.

In the related art, generally, in the mass transfer method, the microLEDs are transferred to an array substrate on which pixel driving circuits are manufactured, so as to form a microLED display panel. The commonly used mass transfer method includes the stamp transfer and the laser transfer. However, neither the stamp transfer nor the laser transfer can balance the transfer rate and the transfer yield. Specifically, the stamp transfer adopts a contact transfer method (the microLEDs are in contact with the array substrate), so the transfer yield is relatively high, but due to the small dimension of the stamp, the transfer rate is relatively low; the laser transfer adopts a non-contact transfer method (the microLEDs are not in contact with the array substrate), and the microLEDs are released through laser irradiation and fall onto the array substrate. Compared with the stamp transfer, the laser transfer has a relatively high rate, but the deviations of the release positions of the microLEDs may occur, resulting in a relatively low transfer yield.

Therefore, how to balance the transfer rate and the transfer yield in the process of transferring the microLEDs is an urgent issue to be solved.

### SUMMARY

The present disclosure provides a mass transfer system and a mass transfer method.

At one aspect, the present disclosure provides a mass transfer system for transferring microLEDs to an array substrate, where the mass transfer system includes a transfer device and a calibration device.

The transfer device is configured to absorb multiple microLEDs and transfer the multiple microLEDs to the calibration device.

The calibration device includes multiple calibration points, where one of the multiple calibration points is configured to absorb one microLED of the multiple microLEDs and perform position calibration on the one microLED of the multiple microLEDs.

The calibration device is further configured to transfer the multiple microLEDs to the array substrate through electrical control.

At the other aspect, based on the same inventive concept, the present disclosure further provides a mass transfer method performed by the mass transfer system provided in any embodiment of the present disclosure, and the mass transfer method includes the steps described below.

A transfer device absorbs multiple microLEDs and transfers the multiple microLEDs to a calibration device.

One calibration point of the calibration device absorbs one microLED of the multiple microLEDs and performs position calibration on the one microLED of the multiple microLEDs.

The calibration device transfers the multiple microLEDs to an array substrate through electrical control.

The mass transfer system provided in the embodiment of the present disclosure includes the transfer device and the calibration device. In the process of transferring the microLEDs, the transfer device transfers the microLEDs to the calibration device, and the position calibration is performed on the microLEDs by using the calibration points on the calibration device.

It is to be understood that the content described in this section is neither intended to identify key or critical features of embodiments of the present disclosure nor intended to limit the scope of the present disclosure. Other features of the present disclosure become easily understood through the description hereinafter.

### BRIEF DESCRIPTION OF DRAWINGS

To illustrate the technical solutions in embodiments of the present disclosure more clearly, drawings used in the description of the embodiments are briefly described below. Apparently, the drawings described below illustrate part of the embodiments of the present disclosure, and those of ordinary skill in the art may obtain other drawings based on the drawings on the premise that no creative work is done.

FIG. 1 is a structural diagram of a mass transfer system according to an embodiment of the present disclosure;

FIG. 2 is a top diagram of a calibration device in a mass transfer system according to an embodiment of the present disclosure;

FIGS. 3 to 5 are transfer flowcharts of the mass transfer system shown in FIG. 1;

FIG. 6 is a section diagram of a calibration device in a mass transfer system according to an embodiment of the present disclosure;

FIG. 7 is a flowchart illustrating positions calibration for microLEDs performed by the calibrating device shown in FIG. 6;

FIG. 8 is another flowchart illustrating positions calibration for microLEDs performed by the calibrating device shown in FIG. 6;

FIG. 9 is a graph illustrating a variation curve of a state of a piezoelectric actuation module corresponding to FIG. 8 during a position calibration process;

FIG. 10 is another section diagram of a calibration device in a mass transfer system according to an embodiment of the present disclosure;

FIG. 11 is another section diagram of a calibration device in a mass transfer system according to an embodiment of the present disclosure;

FIG. 12 is another section diagram of a calibration device in a mass transfer system according to an embodiment of the present disclosure;

FIG. 13 is a structural diagram of another mass transfer system according to an embodiment of the present disclosure;

FIG. 14 is another top diagram of a calibration device in a mass transfer system according to an embodiment of the present disclosure;

FIG. 15 is another top diagram of a calibration device in a mass transfer system according to an embodiment of the present disclosure;

FIG. 16 is another top diagram of a calibration device in a mass transfer system according to an embodiment of the present disclosure;

FIG. 17 is another top diagram of a calibration device in a mass transfer system according to an embodiment of the present disclosure;

FIG. 18 is a top diagram of an array substrate to which a mass transfer system is applicable according to an embodiment of the present disclosure;

FIG. 19 is a top diagram of another array substrate to which a mass transfer system is applicable according to an embodiment of the present disclosure;

FIG. 20 is a top diagram of another array substrate to which a mass transfer system is applicable according to an embodiment of the present disclosure;

FIG. 21 is another top diagram of a calibration device in a mass transfer system according to an embodiment of the present disclosure;

FIG. 22 is a flowchart of a mass transfer method according to an embodiment of the present disclosure;

FIG. 23 is a flowchart of another mass transfer method according to an embodiment of the present disclosure; and

FIG. 24 is a flowchart of another mass transfer method according to an embodiment of the present disclosure.

### DETAILED DESCRIPTION

The technical solutions in embodiments of the present disclosure are described clearly and completely in conjunction with drawings in the embodiments of the present disclosure from which the solutions of the present disclosure are better understood by those skilled in the art. Apparently, the embodiments described below are part, not all, of the embodiments of the present disclosure. Based on the embodiments of the present disclosure, all other embodiments obtained by those of ordinary skill in the art on the premise that no creative work is done are within the scope of the present disclosure.

First, it is to be noted that, unless otherwise defined, the technical terms or scientific terms used in the present disclosure shall have a general meaning understood by those with general skills in the field to which the present disclosure belongs. The terms “first”, “second”, and the like in the present disclosure are used to distinguish between different components but not used to describe any order, quantity, or significance. The term “including”, “comprising”, or the like means that the elements or objects in front of the term cover elements or objects and their equivalents listed in the back of the term, but does not exclude other elements or objects. The term “connected”, “connected to each other”, or the like is not limited to physical or mechanical connections, but may include electrical connections, whether it is direct or indirect. “Up”, “down”, “left”, “right”, and the like are merely used to indicate the relative positional relationship, and when the absolute position of the described object is changed, the relative positional relationship may also change accordingly. In addition, the shape and size of each component in the drawings do not reflect the real scale, and the purpose is only to illustrate the content of the present disclosure.

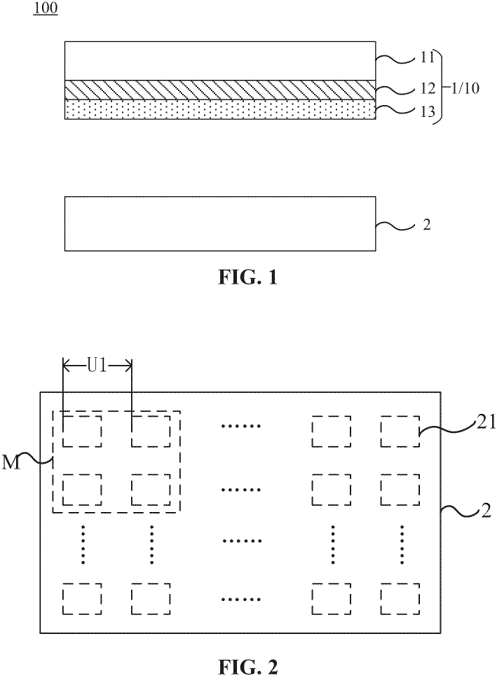

FIG. 1 is a structural diagram of a mass transfer system according to an embodiment of the present disclosure. FIG. 2 is a top diagram of a calibration device in a mass transfer system according to an embodiment of the present disclosure. In conjunction with FIGS. 1 and 2, a mass transfer system 100 provided in the embodiment of the present disclosure includes a transfer device 1 and a calibration device 2. The calibration device 2 includes multiple calibration points 21. The mass transfer system 100 is used for transferring microLEDs to an array substrate. Specifically, in the mass transfer system 100, the transfer device 1 is configured to absorb multiple microLEDs and transfer the microLEDs to the calibration device 2. One calibration point 21 on the calibration device 2 is configured to absorb one microLED and perform position calibration on the microLED. The calibration device 2 is also configured to transfer the microLEDs to the array substrate through electrical control.

The transfer device 1 may be any transfer device capable of picking up/absorbing the microLEDs from a wafer or other substrates and transferring the microLEDs to other substrates (such as the array substrate). In this embodiment, the transfer device 1 first transfers the absorbed microLEDs to the calibration device 2. According to different transfer methods, the mass transfer technology may be divided into the accurate grasping technology, the selective release technology, the transfer printing technology, and the self-assembly technology. Optionally, the transfer device 1 may be any one of a laser transfer device commonly used in the selective release technology, a transfer device that is based on the electrostatic force/Van der Waals force/magnetic force and commonly used in the accurate grasping technology, or a transfer device commonly used in the transfer printing technology, which is not limited in the embodiment of the present disclosure.

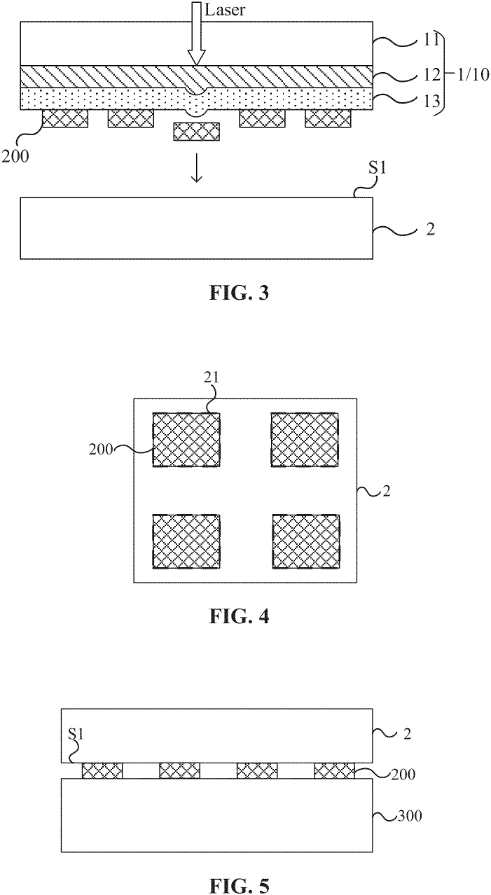

For example, the case where the transfer device 1 is a laser transfer device 10 is used as an example for illustration in FIG. 1. FIGS. 3 to 5 are transfer flowcharts of the mass transfer system shown in FIG. 1. In conjunction with FIGS. 1 and 3, the laser transfer device 10 includes a source substrate 11, a release layer 12, and an adhesive layer 13. The laser transfer device 10 may absorb microLEDs 200 through the adhesive layer 13 and separate the microLEDs 200 from the laser transfer device 10 through laser irradiation so that the microLEDs 200 fall down onto a first surface S1 of the calibration device 2. Specifically, the release layer 12 is irradiated with the single-pulse laser to generate high-pressure gas, the elastic properties of the adhesive layer 13 are used to generate deformation, and then the microLEDs 200 can be pushed to be separated from the laser transfer device 10 and transferred onto the calibration device 2. Since the laser transfer device 10 may release any one of the microLEDs as required, the layout of the microLEDs absorbed on the laser transfer device 10 is not limited to the layout of the calibration points 21 on the calibration device 2, so it is more flexible, and more microLEDs can be absorbed at one time, which is conducive to improving the transfer rate.

As shown in FIG. 2, the calibration device 2 includes multiple calibration points 21, and one calibration point 21 may be configured to absorb one microLED 200 and perform position calibration on the microLED 200, thereby improving the transfer yield. For example, the calibration device can provide a certain adsorption force, such as the electrostatic force or magnetic force, to the microLEDs 200 through the calibration points 21, so as to absorb the microLEDs and calibrate the positions of the microLEDs. For example, FIG. 4 shows the relative positional relationship between the microLEDs 200 and the calibration points 21 after the calibration device 2 calibrating the positions of the microLEDs 200. As shown in FIG. 4, after the position calibration, the geometric center of the microLED 200 nearly coincides with the geometric center of the calibration point 21.

It is to be noted that, in FIG. 4, the case where the orthographic projection region of the microLED 200 on the calibration device 2 overlaps the region where the calibration point 21 is located after the position calibration is used as an example for illustration, which is not limited to this setting method. In other embodiments, the area of the region where the calibration point 21 is located may be greater than or less than the area of the orthographic projection of the microLED 200 on the calibration device.

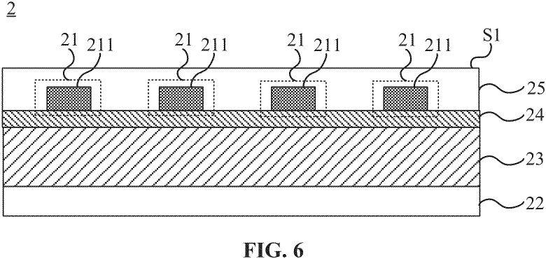

Further, FIG. 5 shows the process in which the calibration device 2 transfers the microLEDs 200 to an array substrate 300. During this process, the first surface S1 of the calibration device 2 on which the microLEDs 200 are absorbed faces the array substrate 300, so as to transfer the microLEDs 200 to the array substrate 300.

Specifically, the layout of the calibration points 21 on the calibration device 2 is related to the layout of the points (receiving points for short) on the array substrate 300 for receiving the microLEDs. The calibration device is moved such that the calibration points 21 are aligned with the corresponding receiving points, and the microLEDs 200 are in contact with the array substrate 300. Then, the micro LEDs 200 may be separated from the calibration device 2 through electrical control, so as to transfer the microLEDs 200 to the array substrate 300. For example, the electrical control method may specifically be to remove the absorption force of the calibration point 21 on the microLED 200.

In this embodiment, since the calibration device 2 performs the position calibration on the microLEDs in advance, thereby improving the transfer yield of the mass transfer. In addition, in the related art, during the stamp transfer, the bonding metal between the microLEDs and the array substrate is generally melted by hot pressing so as to fix the microLEDs on the array substrate. However, due to the different materials of the stamp and the array substrate, the thermal expansion of the stamp and the array substrate at the same temperature is different. It is found through research that the position deviation of the microLEDs at the peripheral edge during hot pressing is more serious. Therefore, to ensure the transfer yield, the dimension of the stamp is generally relatively small, and the number of microLEDs picked up and released each time is limited, leading to a relatively low transfer rate. In the technical solutions of the embodiment of the present disclosure, the calibration device 2 transfers the microLEDs 200 to the array substrate 300 through electrical control without hot pressing so that a large-sized calibration device can be manufactured (for example, the dimension of the calibration device may be comparable to the dimension of the array substrate), and more microLEDs can be transferred at one time, thereby ensuring a relatively high transfer rate. Moreover, the large-sized calibration device is designed so that the position calibration can be performed on more microLEDs at one time, thereby shortening the time used for position calibration, which is also conducive to ensuring a relatively high transfer rate.

After the microLEDs are transferred to the array substrate, the bonding metal may be melted by laser ablation or other methods to achieve the electrical connection between the microLEDs and pixel driving circuits in the array substrate, which is not limited in the embodiment of the present disclosure.

It is to be noted that the layout of the calibration points 21 shown in FIG. 2 is merely illustrative and not limiting. Specifically, the layout of the calibration points 21 may be designed in conjunction with the actual layout of the receiving points on the array substrate, which is not limited in the embodiment of the present disclosure.

Additionally, it is to be noted that, in FIG. 5, the case where the microLEDs 200 are in contact with the array substrate 300 when the calibration device 2 transfers the microLEDs 200 to the array substrate 300 is used as an example for illustration. In other embodiments, a small gap exists between the microLED 200 and the array substrate 300 so that the transfer yield is not affected, and at the same time, the microLEDs can be prevented from being damaged at the moment of being in contact with the array substrate, thereby ensuring the quality of the microLEDs.

To sum up, the mass transfer system provided in the embodiment of the present disclosure is provided with the calibration device. In the process of transferring the microLEDs, the transfer device transfers the microLEDs to the calibration device, and the position calibration is performed on the microLEDs by using the calibration points on the calibration device, thereby improving the transfer yield. At the same time, since the microLEDs are transferred from the calibration device to the array substrate through electrical control without hot pressing, a larger-sized calibration device can be manufactured so that more microLEDs can be transferred at one time and the position calibration can be performed on more microLEDs at one time, thereby ensuring a relatively high transfer rate.

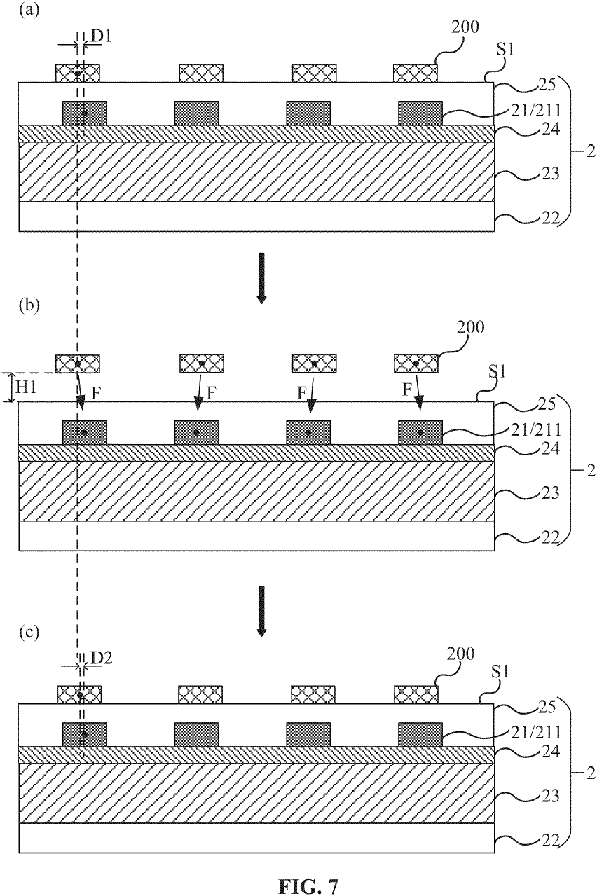

Based on the preceding embodiments, FIG. 6 is a section diagram of a calibration device in a mass transfer system according to an embodiment of the present disclosure, and FIG. 7 is a flowchart illustrating positions calibration for microLEDs performed by the calibrating device shown in FIG. 6, showing the states of the microLEDs and the calibration device at different moments in one calibration cycle. As shown in FIGS. 6 and 7, optionally, the calibration device 2 further includes a substrate 22 and a piezoelectric actuation module 23 located on the substrate 22, each calibration point 21 includes at least one absorption electrode 211, and the at least one absorption electrode 211 is located on a side of the piezoelectric actuation module 23 facing away from the substrate 22. A process of position calibration includes at least one calibration cycle, and one calibration cycle includes a first stage and a second stage performed in sequence (in FIG. 7, (a) shows the state at the beginning of the calibration cycle, (b) shows the state at the end of the first stage, and (c) shows the state at the end of the second stage, that is, the state at the end of the calibration cycle). In the first stage (as shown in FIGS. 7 (a) and (b)), the calibration device 2 is configured to control the generation of a first gap H1 between the microLEDs 200 and the first surface S1 of the calibration device 2 through the piezoelectric actuation module 23. In the second stage (as shown in FIGS. 7 (b) and (c)), the calibration device 2 is configured to provide electrostatic attraction F to the microLEDs 200 through absorption electrodes 211 to control the microLEDs 200 to fall back onto the first surface S1. The first surface S1 is located on a side of the absorption electrodes 211 facing away from the substrate 22.

A positive voltage signal or a negative voltage signal may be applied to the absorption electrode 211, which is not limited in the embodiment of the present disclosure. An electrical signal is applied to the absorption electrode 211 so that an electric field can be generated in the region where the calibration point 21 is located, and polarized charges are generated on the surface of a material with a dielectric constant under the action of the electric field. Therefore, an electrostatic force exists between the microLED 200 and the absorption electrode 211, the direction of the electrostatic force is from the geometric center of the microLED 200 to the geometric center of the position of the absorption electrode 211 (that is, the calibration point 21), and the electrostatic force is expressed as the electrostatic attraction of the calibration point 21 to the microLED 200. Specifically, during the process in which the transfer device 1 transfers the microLEDs 200 to the calibration device 2 and the calibration device 2 performs the positions calibration on the microLEDs 200, the absorption electrodes in the calibration points 21 for absorbing the microLEDs need to be kept powered on at all times. In addition, the region where one calibration point 21 is located may be understood as the region surrounded by the outermost edges of all the absorption electrodes 211 in the calibration point 21, so as to determine the geometric center of the calibration point.

It is to be noted that, in FIG. 6, the case where one calibration point 21 includes one absorption electrode 211 is used as an example for illustration. The positive voltage signal or the negative voltage signal may be applied to the absorption electrode 211, which is not limited in the embodiment of the present disclosure. In addition, in other embodiments, one calibration point 21 may include multiple absorption electrodes 211, and the voltage signals applied to the absorption electrodes 211 may be the same or different, which is not limited in the embodiment of the present disclosure.

Additionally, it is to be noted that the electrical signals may be applied to the absorption electrodes 211 in all calibration points at the same time, or the electrical signals 211 may be separately applied to the absorption electrodes 211 in the respective calibration point, which is not limited in the embodiment of the present disclosure.

The case where the transfer device 1 is the laser transfer device is used as an example. Although the absorption electrodes 211 may provide the electrostatic attraction to the microLEDs 200 when the transfer device 1 transfers the microLEDs 20 to the calibration device 2, since the friction exists when the microLEDs 200 are in contact with the calibration device 2, it is difficult for the absorption electrodes 211 to complete the position calibration on the microLED 200 during one drop, and the position deviation between the geometric center of the microLED 200 and the geometric center of the calibration point 21 is relatively large. In the embodiment of the present disclosure, the calibration device 2 is configured to include the piezoelectric actuation module 23, and the calibration device 2 may control the piezoelectric actuation module 23 to generate the first gap H1 between the microLED 200 and the first surface S1 for multiple times, thereby creating the condition for multiple times of falling of the microLED 200, performing multiple position calibrations on the microLED 200 through the at least one absorption electrode 211, and improving the control accuracy and the transfer yield.

Specifically, the piezoelectric actuation module 23 mainly includes a piezoelectric material (such as piezoelectric ceramics) and electrodes located on two sides of the piezoelectric material along a direction perpendicular to the substrate 22. The voltages applied to the electrodes are controlled, so as to control the expansion and contraction of the piezoelectric material. In this manner, the expansion and contraction process of the piezoelectric actuation module 23 is cleverly designed so that in the first stage, the piezoelectric actuation module 23 is configured to control the generation of the first gap H1 between the microLED 200 and the first surface S1 of the calibration device 2, thereby creating the falling condition for the microLED 200. In this manner, in the process of the microLED 200 falling back onto the first surface S1 (that is, the second stage), the at least one absorption electrodes 211 provide the electrostatic attraction F to the microLED 200. Since the electrostatic attraction F is directed from the geometric center of the microLED 200 to the geometric center of the calibration point 21, the microLED 200 can move toward the center of the calibration point under the action of the electrostatic attraction F during the falling process, so as to perform the position calibration.

For example, in FIG. 7, (a) shows the relative positional relationship between the microLEDs 200 and the calibration points 21 when the transfer device 1 transfers the microLEDs to the first surface S1 of the calibration device 2. As can be seen from FIG. 7 (a), a position deviation D1 exists between the geometric center of the microLED 200 and the geometric center of the calibration point 21. After one calibration cycle, as shown in FIG. 7 (c), the position deviation between the geometric center of the microLED 200 and the geometric center of the calibration point 21 is reduced to D2. In this manner, after multiple calibration cycles, the geometric center of the microLED 200 nearly coincides with the geometric center of the calibration point 21, so as to complete the position calibration.

For example, the staff may observe the completion of the position calibration of the microLEDs 200 through a microscope, but this detection method takes a long time and certain errors may exist. In an embodiment, optionally, the mass transfer system further includes a calibration detection device. Referring to FIG. 7 (c), the calibration detection device is configured to collect a first position of the geometric center of the microLED 200 and a second position of the geometric center of the calibration point 21 corresponding to the microLED 200 and determine a position calibration result according to the relative distance (for example, D2) between the first position and the second position. Specifically, the calibration detection device may determine that the position calibration is completed in the case where the relative distance between the first position and the second position is approximately zero. For example, the calibration detection device may be an image sensor. The calibration detection device determines the completion of position calibration, saving time and improving the detection efficiency and detection accuracy compared to manual detection.

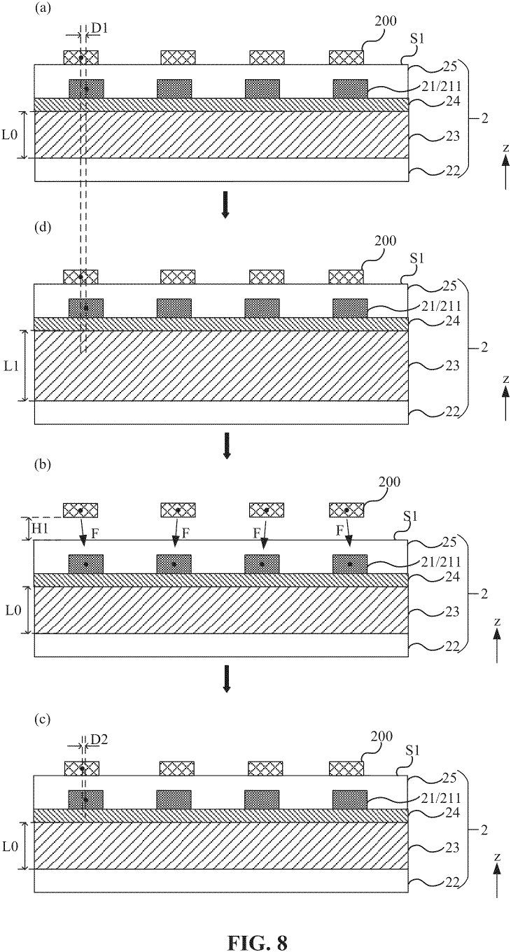

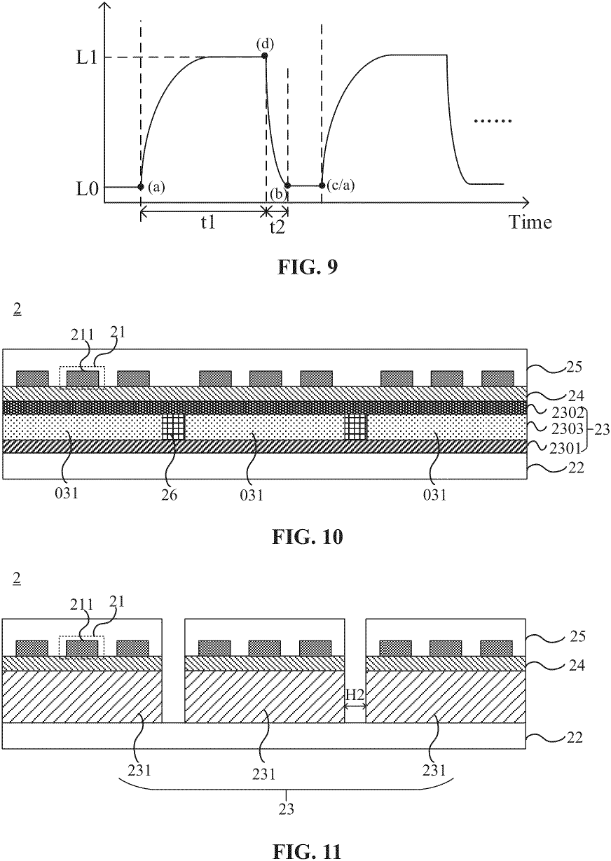

Further, FIG. 8 is another flowchart illustrating positions calibration for microLEDs performed by the calibrating device shown in FIG. 6. Based on the preceding embodiments, the first stage of the calibration cycle is further refined, and the similarities are not repeated here. As shown in FIG. 8, FIG. 8 shows the states of the microLEDs and the calibration devices at different moments in one calibration cycle. Specifically, in FIG. 8, (a) shows the state at the beginning of the calibration cycle, (d) shows the state at the end of the first process in the first stage, (b) shows the state at the end of the second process in the first stage, that is, the state at the end of the first stage, and (c) shows the state at the end of the second stage, that is, the state at the end of the calibration cycle. In addition, FIG. 9 is a graph illustrating a variation curve of a state of a piezoelectric actuation module corresponding to FIG. 8 during a position calibration process. In conjunction with FIGS. 8 and 9, optionally, the first stage includes the first process and the second process performed in sequence. In the first process ((a) to (d)), the calibration device 2 is configured to control the piezoelectric actuation module 23 to expand from an initial state (L0) to a first state (L1) along a first direction z within a first duration t1, where the first direction z is perpendicular to a plane where the substrate 22 is located. In the second process ((d) to (b)), the calibration device 2 is configured to control the piezoelectric actuation module 23 to contract from the first state (L1) to the initial state (L0) along the first direction z within a second duration t2 so that the first gap H1 is formed between the microLED 200 and the first surface S1. The first duration t1 is at least ten times the second duration t2.

Referring to FIG. 8, the initial state may be characterized by the initial thickness L0 of the piezoelectric actuation module 23 in the first direction z, and the first state may be characterized by the thickness L1 of the expanded piezoelectric actuation module 23.

Specifically, in the first process, the piezoelectric actuation module 23 is controlled to slowly expand from the initial state (L0) to the first state (L1) along the first direction z within the first duration t1. In this process, since the microLEDs 200 are bound by the electrostatic force of the absorption electrodes 211, the microLEDs 200 are in close contact with the first surface S1 of the calibration device 2 and move along with the calibration device 2 toward a direction facing away from the substrate 22 by a distance Δz (Δz = L1 - L0) so that the microLEDs 200 are elevated. In the second process, the piezoelectric actuation module 23 is controlled to rapidly contract from the first state (L1) to the initial state (L0) along the first direction z within the second duration t2. In this process, due to inertia, the microLEDs 200 do not fall back along with the calibration device 2, but stay in mid-air so that the first gap H1 is generated between the microLED 200 and the first surface S1 of the calibration device 2, thereby creating the falling condition for the microLEDs 200.

According to physical knowledge, it is easy to understand that in the first process, if the piezoelectric actuation module 23 expands from the initial state to the first state in a relatively short period of time, the microLEDs 200 are freed from the bondage of the electrostatic force due to inertia, and the microLEDs 200 pop up from the calibration device 2. Specifically, the speed of the expansion process of the piezoelectric actuation module 23 first increases and then decreases to zero. A voltage is applied to the piezoelectric actuation module 23 so that the piezoelectric actuation module 23 can instantly have the initial speed of expansion, the acceleration process may be ignored, and the expansion process is mainly a deceleration process. If the deceleration time is too short (the expansion is too fast), the microLEDs 200 overcome the electrostatic force due to excessive inertia and pop up from the first surface S1, which is similar to the case where a person falls forward due to a sudden brake while driving. Therefore, the piezoelectric actuation module 23 needs to be controlled to slowly expand. In an embodiment, optionally, the first duration is 10 µs to 100 µs, so as to ensure that the microLEDs 200 are in close contact with the first surface S1 of the calibration device 2 and move upward along the first direction z in the first process and the microLEDs 200 are elevated.

Similarly, in the second process, if the piezoelectric actuation module 23 contracts from the first state to the initial state within a relatively long period of time, the microLEDs 200 are in close contact with the first surface S1 of the calibration device 2 and fall back to the initial position along with the calibration device 2, the first gap cannot be formed between the microLEDs 200 and the calibration device 2, and then the calibration cannot be performed, which is similar to the case where when taking an elevator, a person falls with the elevator without staying in mid-air since the elevator falls slowly. Therefore, the piezoelectric actuation module 23 needs to be controlled to rapidly contract. In an embodiment, optionally, the second duration is less than 1 µs so that the first gap H1 is generated between the microLED 200 and the calibration device 2, thereby creating the falling condition for the microLEDs and performing the position calibration on the microLEDs 200 through the electrostatic attraction provided by the absorption electrodes 211 during the falling process of the microLEDs 200.

Based on the same concept, referring to FIG. 5, the calibration device 2 transfers the microLEDs 200 to the array substrate 300 through electrical control, and the calibration device 2 may control the piezoelectric actuation module to rapidly contract so that the microLEDs 200 are separated from the first surface S1 of the calibration device 2, and microLEDs 200 are transferred to the array substrate 300.

To sum up, in the preceding embodiments, the main working principle of the calibration device performing position calibration on the microLEDs is described in detail, and the structure of the calibration device is further described below.

Optionally, the calibration device 2 includes a controller, where the controller is electrically connected to the absorption electrodes 211 and the piezoelectric actuation module 23 separately and can independently control the power supply states of the absorption electrodes 211 and the piezoelectric actuation module 23.

As shown in FIG. 6, optionally, the calibration device 2 further includes an insulating substrate 24 and a protective layer 25. The insulating substrate 24 is located between the absorption electrodes 211 and the piezoelectric actuation module 23 and plays the role of electrical insulation. For example, the insulating substrate 24 may be a glass substrate or a silicon substrate, and of course, may also be another material of insulating substrate known to those skilled in the art, which is not limited in the embodiment of the present disclosure. The protective layer 25 covers the absorption electrodes 211 to protect the absorption electrodes 211 and prevent the microLEDs 200 from being in direct contact with the absorption electrodes 211. For example, the material of the protective layer 25 may be a stable insulating material such as polytetrafluoroethylene, silicon oxide, or silicon nitride, which is not limited in the embodiment of the present disclosure.

FIG. 10 is another section diagram of a calibration device in a mass transfer system according to an embodiment of the present disclosure. As shown in FIG. 10, optionally, the piezoelectric actuation module 23 includes a bottom electrode layer 2301, a top electrode layer 2302, and a piezoelectric material layer 2303 between the bottom electrode layer 2301 and the top electrode layer 2302, where the top electrode layer 2302 is located on a side of the bottom electrode layer 2301 facing away from the substrate 22. The piezoelectric material layer 2303 includes multiple piezoelectric units 031, and an insulating bank 26 is provided between two adjacent piezoelectric units 031.

Specifically, by controlling the voltage applied to the bottom electrode layer 2301 and the voltage applied to the top electrode layer 2302, the expansion and contraction of the piezoelectric material layer 2303 is controlled, so as to create the falling condition for the microLEDs.

The preparation process of the large-area piezoelectric material is relatively complicated. In this embodiment, the piezoelectric material layer 2303 includes multiple piezoelectric units 031, and the insulating bank 26 is provided between two adjacent piezoelectric units 031 so that the manufacturing of a large-sized piezoelectric material layer is converted into the manufacturing of multiple small-sized piezoelectric units, thereby reducing the process difficulty. In addition, with this arrangement, no gap exists in the film layers below the top electrode layer 2302, which is conducive to manufacturing a whole layer of the top electrode layer 2302 and reducing the difficulty of wiring. In addition, in this case, all the piezoelectric units 031 share the same top electrode layer 2302 and the same bottom electrode layer 2301 so that the expansion and contraction of the piezoelectric units 031 can be controlled at the same time, and the position calibration can be performed on all the microLEDs at the same time, thereby shortening the time used for position calibration and improving the transfer rate.

FIG. 11 is another section diagram of a calibration device in a mass transfer system according to an embodiment of the present disclosure. As shown in FIG. 11, in other embodiments, optionally, the piezoelectric actuation module 23 includes multiple piezoelectric actuation units 231, and a second gap H2 exists between two adjacent piezoelectric actuation units 231.

Specifically, the piezoelectric actuation unit 231 also includes the piezoelectric material layer, top electrodes on the upper side of the piezoelectric material layer and bottom electrodes on the lower side of the piezoelectric material layer. The difference is that the dimension of the piezoelectric actuation unit 231 is relatively small. In this manner, the manufacturing of the large-sized piezoelectric material can also be avoided, thereby reducing the process difficulty and improving the product yield.

In this embodiment, the second gap H2 exists between two adjacent piezoelectric actuation units 231. In this case, the controller can independently control the expansion and contraction of each piezoelectric actuation unit 231 and can also control the expansion and contraction of the piezoelectric actuation units 231 at the same time, which is not limited in the embodiment of the present disclosure. For example, in any manner, the bottom electrodes of all the piezoelectric actuation units may be electrically connected to the same signal terminal of the controller, and the top electrodes of all the piezoelectric actuation units may be electrically connected to the other signal terminal of the controller, so as to control the expansion and contraction of the piezoelectric actuation units at the same time.

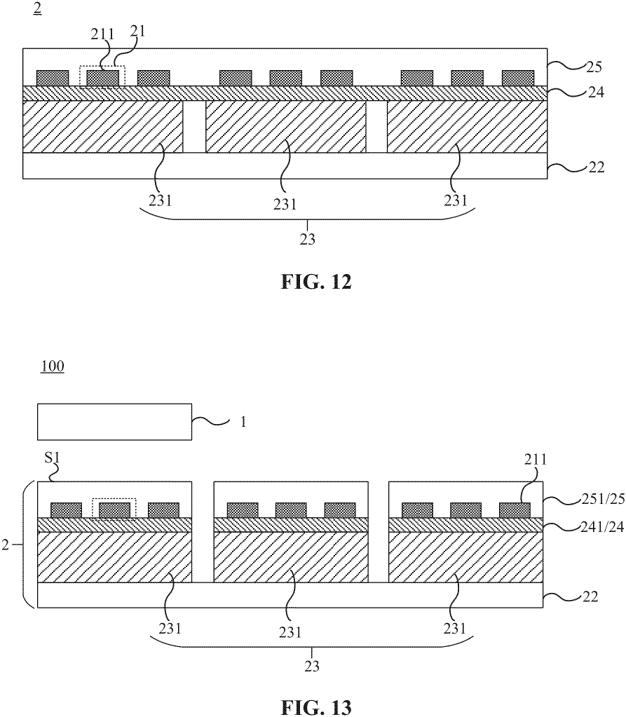

It is to be noted that, in FIG. 11, the case where the insulating substrate 24 and the protective layer 25 are correspondingly divided into multiple parts corresponding to the piezoelectric actuation units 231 and the orthographic projection of each part of the insulating substrate 24 and the protective layer 25 on the substrate 22 covers one piezoelectric actuation unit 231 is used as an example for illustration, which is not limited to this setting method. FIG. 12 is another section diagram of a calibration device in a mass transfer system according to an embodiment of the present disclosure. As shown in FIG. 12, in other embodiments, in the case where the piezoelectric actuation module 23 includes multiple piezoelectric actuation units 231 and the second gap H2 exists between two adjacent piezoelectric actuation units 231, the insulating substrate 24 and the protective layer 25 may not be divided. In other words, the orthographic projection of the insulating substrate 24 on the substrate 22 covers all the piezoelectric actuation units 231, and the orthographic projection of the protective layer 25 on the substrate 22 covers all the piezoelectric actuation units 231.

FIG. 13 is a structural diagram of another mass transfer system according to an embodiment of the present disclosure. As shown in FIG. 13, further optionally, the dimension of the orthographic projection of the transfer device 1 on the substrate 22 is less than or equal to the dimension of the orthographic projection of the piezoelectric actuation unit 231 on the substrate 22.

In this manner, the dimension of the transfer device 1 can be reduced and the difficulty of manufacturing the transfer device can be reduced. In addition, the microLEDs absorbed on the transfer device 1 may be correspondingly transferred to the first surface S1 on a side of one piezoelectric actuation unit 231 facing away from the substrate 22, each piezoelectric actuation unit 231 is used to create the falling condition for the corresponding microLED, so that the control method is more flexible.

For example, the case where the transfer device 1 is the laser transfer device is used as an example. Since the layout of the microLEDs absorbed on the laser transfer device is not limited to the layout of the calibration points 21 on the calibration device 2, the distance between two adjacent microLEDs on the laser transfer device may be smaller. Therefore, the dimension of the orthographic projection of the laser transfer device on the substrate may be less than the dimension of the orthographic projection of the piezoelectric actuation unit 231 on the substrate. If the layout of the microLEDs on the transfer device is limited by the layout of the calibration points 21 on the calibration device 2, the transfer device 1 may be configured to have the same dimension as the piezoelectric actuation unit 231. In other words, the dimension of the orthographic projection of the transfer device 1 on the substrate 22 is equal to the dimension of the orthographic projection of the piezoelectric actuation unit 231 on the substrate 22. Of course, due to the limitation of process accuracy, a certain error exists between the dimensions of the orthographic projections of the transfer device 1 and the piezoelectric actuation unit 231, as long as the dimensions are approximately equal.

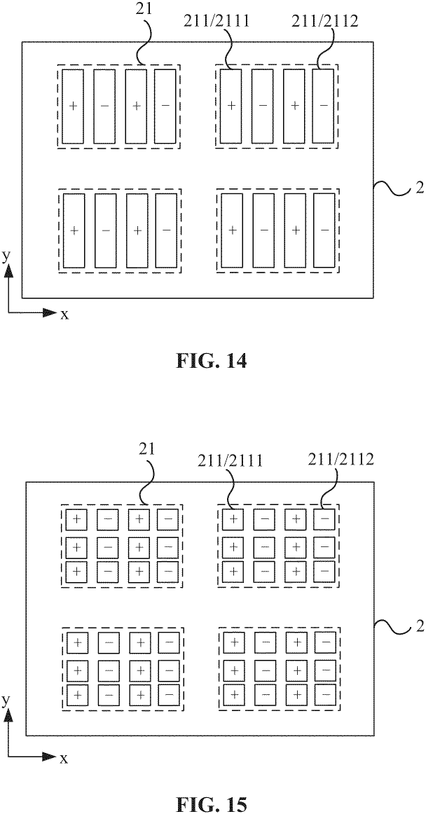

FIG. 14 is another top diagram of a calibration device in a mass transfer system according to an embodiment of the present disclosure. As shown in FIG. 14, optionally, at least one absorption electrode 211 in one calibration point 21 includes at least one first electrode 2111 and at least one second electrode 2112, where the number of first electrodes 2111 is equal to the number of second electrodes 2112, and the polarity of the voltage applied to the first electrode 2111 and the polarity of the voltage applied to the second electrode 2112 are opposite. For example, in FIG. 14, the case where a positive voltage signal is applied to the first electrode 2111 and a negative voltage signal is applied to the second electrode 2112 is used as an example for illustration. In other embodiments, the negative voltage signal may be applied to the first electrode 2111, and the positive voltage signal may be applied to the second electrode 2112, which is not limited in the embodiment of the present disclosure. In this embodiment, one calibration point 21 is configured to include the first electrodes 2111 and the second electrodes 2112 with the same number as each other and opposite polarities of the applied voltages so that the position calibration accuracy of the electric field to the microLEDs can be further improved.

With continued reference to FIG. 14, optionally, at least one absorption electrode 211 in one calibration point 21 includes at least two first electrodes 2111 and at least two second electrodes 2112. Along a second direction x, the first electrodes 2111 and the second electrodes 2112 are arranged alternately; or along a third direction y, the first electrodes 2111 and the second electrodes 2112 are arranged alternately (not shown in FIG. 14), where the second direction x and the third direction y intersect and are parallel to the plane where the substrate is located.

The microLED includes an anode pad and a cathode pad. When the microLED is transferred to the array substrate, the anode pad and the cathode pad of the microLED need to be separately in contact with the corresponding bonding metal on the array substrate. Therefore, after the transfer device absorbs the microLED, the anode pad and cathode pad of the microLED generally have an initial arrangement direction, so as to ensure the accuracy and reliability of the final bonding between electrodes. After the transfer device transfers the microLED to the calibration device, a deviation (such as a certain distance in translation or a slight rotation at a certain angle) may exist between the position of the microLED and the position of the calibration point. This solution is adopted so that the calibration device performs the position calibration on the microLED, the geometric center of the microLED approximately coincides with the geometric center of the calibration point, and the arrangement direction of the anode pad and cathode pad of the microLED return to the initial arrangement direction. Specifically, in this embodiment, optionally, one of the second direction x or the third direction y is parallel to the initial arrangement direction, and the other one of the second direction x or the third direction y is orthogonal to the initial arrangement direction, so as to ensure the completion of the position calibration of the microLED under the action of the electric field.

For example, in FIG. 14, the case where the first electrodes 2111 and the second electrodes 2112 are arranged alternately along the second direction x is used as an example for illustration. In other embodiments, referring to FIG. 14, the first electrodes 2111 and the second electrodes 2112 are arranged alternately along the third direction y.

It is to be noted that in the case where the first electrodes 2111 and the second electrodes 2112 are arranged alternately along the second direction x, in FIG. 14, the case where the first electrodes 2111 and the second electrodes 2112 are strip electrodes extending along the third direction y is used as an example for illustration, which is not limited to this setting method. FIG. 15 is another top diagram of a calibration device in a mass transfer system according to an embodiment of the present disclosure. As shown in FIG. 15, in other embodiments, in the case where the first electrodes 2111 and the second electrodes 2112 are arranged alternately along the second direction x, along the third direction y, multiple first electrodes 2111 may be arranged side by side and multiple second electrodes 2112 may be arranged side by side. A setting method in which the first electrodes 2111 and the second electrodes 2112 are arranged alternately along the third direction y is similar to this setting method. The details are not repeated here.

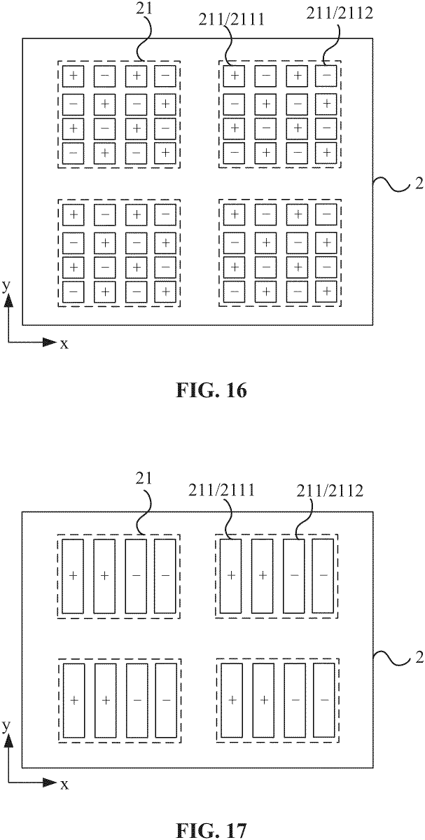

It is to be noted that, in the preceding embodiment, the case where the first electrodes 2111 and the second electrodes 2112 are arranged alternately along the second direction x or the third direction y is used as an example, which is not limited to this setting method. FIG. 16 is another top diagram of a calibration device in a mass transfer system according to an embodiment of the present disclosure. As shown in FIG. 16, in other embodiments, the first electrodes 2111 and the second electrodes 2112 are arranged alternately along the second direction x, and the first electrodes 2111 and the second electrodes 2112 are also arranged alternately along the third direction y.

In the case where one calibration point 21 includes both the first electrode 2111 and the second electrode 2112, in the entire electric field formed by the absorption electrode 211 in the calibration point 21, the electric field between one first electrode (such as a positive electrode) and one second electrode (such as a negative electrode) with opposite polarities of the applied voltages may form a calibration field for the microLED, and the span of the positive electrode and the negative electrode affects the fineness of the calibration field. In the embodiment of the present disclosure, the first electrodes 2111 and the second electrodes 2112 are arranged alternately along the second direction x, and/or the first electrodes 2111 and the second electrodes 2112 are arranged alternately along the third direction y, thereby improving the division fineness of the calibration field, improving the fineness of the control of the microLEDs, and improving the position calibration accuracy.

FIG. 17 is another top diagram of a calibration device in a mass transfer system according to an embodiment of the present disclosure. As shown in FIG. 17, in other embodiments, in the case where one calibration point 21 includes multiple first electrodes 2111 and multiple second electrodes 2112, the multiple first electrodes 2111 and the multiple second electrodes 2112 may be arranged symmetrically along the second direction x, that is, along the second direction x, the multiple first electrodes 2111 and the multiple second electrodes 2112 are separately on two sides of the region where the calibration point 21 is located, and the first electrodes 2111 and the second electrodes 2112 are symmetrical about the central axis of the calibration point 21 along the second direction x. Of course, in other embodiments, the multiple first electrodes 2111 and the multiple second electrodes 2112 may also be arranged symmetrically along the third direction y. Alternatively, the multiple first electrodes 2111 and the multiple second electrodes 2112 are arranged symmetrically along the second direction x, and the multiple first electrodes 2111 and the multiple second electrodes 2112 are arranged symmetrically along the third direction y, which is not limited in the embodiment of the present disclosure. This setting method is adopted, so as to perform the position calibration on the microLEDs.

Referring to FIG. 17, optionally, the area of the orthographic projection region of the microLED on the calibration device 2 is greater than the area of the region where the calibration point 21 is located. In other words, after the position calibration of the microLED is completed so that the geometric center of the microLED approximately coincides with the geometric center of the calibration point 21, the orthographic projection of the microLED on the calibration device 2 covers the region where the calibration point 21 is located.

If the area of the orthographic projection region of the microLED on the calibration device is less than the area of the region where the calibration point is located, during the position calibration process, in the case where the microLED is within the region where the calibration point is located, if the position deviation between the microLED and the calibration point is relatively small, the inhomogeneity of the electric field felt by the microLED is not apparent, and the calibration force is relatively weak. Therefore, in this embodiment, the area of the orthographic projection region of the microLED on the calibration device is greater than the area of the region where the calibration point is located. Even if a slight deviation exists between the geometric center of the microLED and the geometric center of the calibration point, the uneven distribution of the polarized charges on the microLED caused by the electric field is more apparent, and the inhomogeneity of the electric field felt by the microLED is also relatively apparent so that the calibration force is relatively strong, which is conducive to ensuring the position calibration accuracy.

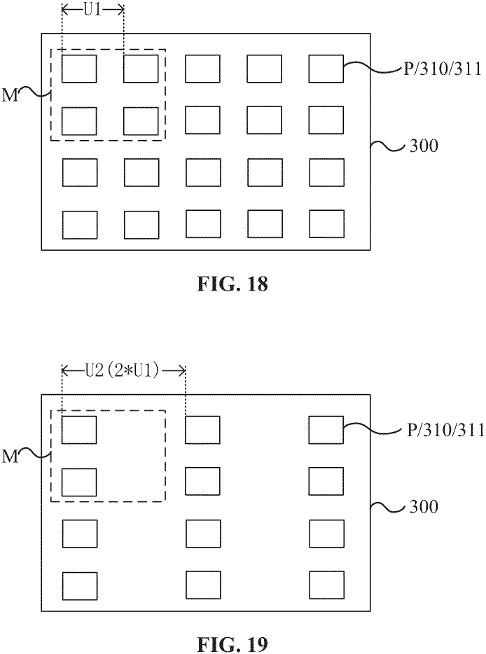

FIG. 18 is a top diagram of an array substrate to which a mass transfer system is applicable according to an embodiment of the present disclosure. As shown in FIG. 18, the array substrate 300 includes multiple receiving units 310 arranged in one-to-one correspondence with multiple sub-pixels P. Comparing FIG. 2 with FIG. 18, optionally, the number of the calibration points 21 per unit area M is greater than or equal to the number of the receiving units 310 per unit area M. For example, in FIG. 2, four calibration points 21 exist per unit area M, and in FIG. 18, the case where four receiving units 310 exist per unit area M is used as an example for illustration. In other embodiments, the number of the calibration points 21 per unit area M may be greater than the number of the receiving units 310 per unit area M, which is exemplified below.

Specifically, a microLED display panel includes multiple sub-pixels. One sub-pixel generally includes a microLED and a pixel circuit in the array substrate for providing a drive current for the microLED. The receiving unit 310 is a bridge for connecting the microLED and the pixel circuit. In the embodiment of the present disclosure, the number of the calibration points 21 per unit area M is configured to be greater than or equal to the number of the receiving units 310 per unit area M so that the calibration device is applicable to a variety of different array substrates at the same time, thereby improving the practicability of the calibration device. The detailed description is made below in conjunction with the embodiments.

With continued reference to FIG. 18, optionally, one receiving unit 310 includes one receiving point 311 for receiving one microLED. Comparing FIG. 2 with FIG. 18, the number of the calibration points 21 per unit area M is N times the number of the receiving points 311 per unit area M, where N is a positive integer. For example, the number of the calibration points 21 per unit area M in FIG. 2 is the same as the number of the receiving points 311 per unit area M in FIG. 18, that is, the case where N = 1 is used as an example for illustration. In this case, the distance (such as U1) between two adjacent calibration points 21 in any direction (such as a row direction) may be configured to be the same as the distance (such as U1) between two adjacent receiving points 311 in this direction so that the distribution density of the calibration points 21 is the same as the distribution density of the receiving points 311. In this manner, when the calibration device 2 is used to transfer the microLEDs to the array substrate 300, the calibration device 2 may be moved to make the calibration points 21 aligned with the receiving points 311, and then the microLEDs are transferred to the array substrate 300 through electrical control. Since the positions of the microLEDs are calibrated, a high transfer yield can be ensured. In an embodiment, in the case where N = 1, the total number of the calibration points 21 on the calibration device 2 may be configured to be equal to the total number of the receiving points 311 on the array substrate 300. In this case, after all the microLEDs are transferred to the calibration device 2, the position calibration is performed on all the microLEDs at one time, and the calibration device 2 is used to transfer all the microLEDs to the array substrate 300 at one time, thereby significantly increasing the transfer rate.

FIG. 19 is a top diagram of another array substrate to which a mass transfer system is applicable according to an embodiment of the present disclosure. In FIG. 19, one receiving unit 310 includes one receiving point 311 and can receive one microLED. The difference between the array substrate shown in FIG. 19 and the array substrate shown in FIG. 18 lies in that the distribution densities of the receiving points 311 are different. For example, the case where the distance U2 between two adjacent receiving points 311 along the row direction in FIG. 19 is twice the distance U1 between two adjacent receiving points 311 along the row direction in FIG. 18 is used as an example for illustration. In this case, the distribution density of the receiving points 311 in FIG. 19 is half the distribution density of the receiving points 311 in FIG. 18 so that the resolution of the display panel corresponding to FIG. 18 is twice the resolution of the display panel corresponding to FIG. 19. Comparing FIG. 2 with FIG. 19, the number of the calibration points 21 per unit area M in FIG. 2 is greater than the number of the receiving points 311 per unit area in FIG. 19, and the number of the calibration points 21 per unit area M in FIG. 2 is twice the number of the receiving points 311 per unit area in FIG. 19 (that is, N = 2). In this case, the calibration device 2 shown in FIG. 2 may be used to transfer the microLEDs to the array substrate 300 shown in FIG. 19. Specifically, the calibration points in odd or even columns may be used to absorb the microLEDs and perform the position calibration on the microLEDs, and then the calibration device is moved so that the calibration points at which the microLEDs are absorbed are aligned with the receiving points of the array substrate, and the microLEDs are transferred to the array substrate.

To sum up, in the case where one receiving unit 310 includes one receiving point, in this embodiment, the number of the calibration points 21 per unit area M may be configured to be N times the number of the receiving points 311 per unit area M so that one calibration device is applicable to the manufacture of multiple display panels with resolutions in multiples at the same time, and the position-calibrated microLEDs are transferred to the array substrates corresponding to the display panels, thereby ensuring relatively high practicability.

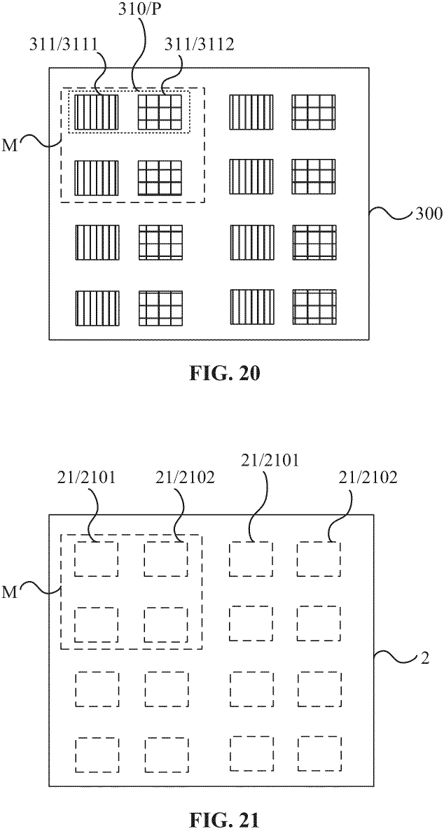

In addition, in other embodiments, one receiving unit 310 may include multiple receiving points 311. For example, FIG. 20 is a top diagram of another array substrate to which a mass transfer system is applicable according to an embodiment of the present disclosure. As shown in FIG. 20, optionally, one receiving unit 310 includes one first receiving point 3111 and one second receiving point 3112, where at least one of the first receiving point 3111 or the second receiving point 3112 is configured to receive the microLED. Correspondingly, FIG. 21 is another top diagram of a calibration device in a mass transfer system according to an embodiment of the present disclosure. In conjunction with FIGS. 20 and 21, optionally, multiple calibration points 21 include multiple first calibration points 2101 and multiple second calibration points 2102, where the first calibration point 2101 is provided corresponding to the first receiving point 3111, and the second calibration point 2102 is provided corresponding to the second receiving point 3112.

In this embodiment, one receiving unit 310 includes two receiving points 311, that is, the first receiving point 3111 and the second receiving point 3112, one of the first receiving point 3111 or the second receiving point 3112 (for example, the first receiving point 3111) may be configured to receive the microLED, and the other one of the first receiving point 3111 or the second receiving point 3112 (for example, the second receiving point 3112) is configured to be a redundant receiving point. In this manner, in the case where it is detected that the microLED at the first receiving point 3111 cannot emit light normally, a new microLED may be re-bonded at the second receiving point 3112, so as to ensure that the sub-pixel corresponding to the receiving unit 310 can display normally. Specifically, the first receiving point 3111 and the second receiving point 3112 in one receiving unit 310 are both electrically connected to the pixel circuit in the sub-pixel corresponding to the receiving unit 310. In the case where it is determined that the microLED bonded for the first time cannot emit light normally, the electrical connection between the microLED and the pixel circuit may be cut off, and a new microLED may be bonded at the other receiving point, so as to ensure that the sub-pixel can display normally.

Correspondingly, referring to FIGS. 20 and 21, in this embodiment, on the calibration device 2, the first calibration point 2101 is provided corresponding to the first receiving point 3111, and the second calibration point 2102 is provided corresponding to the second receiving point 3112. In addition, it is satisfied that the number of the calibration points 21 per unit area M is greater than the number of the receiving units 310 per unit area M. In this manner, the first calibration point 2101 or the second calibration point 2102 may be configured to absorb the microLED according to actual requirements, the position calibration is performed on the microLED, and then the microLED is transferred to the first receiving point 3111 or the second receiving point 3112, thereby improving the practicability of the calibration device.

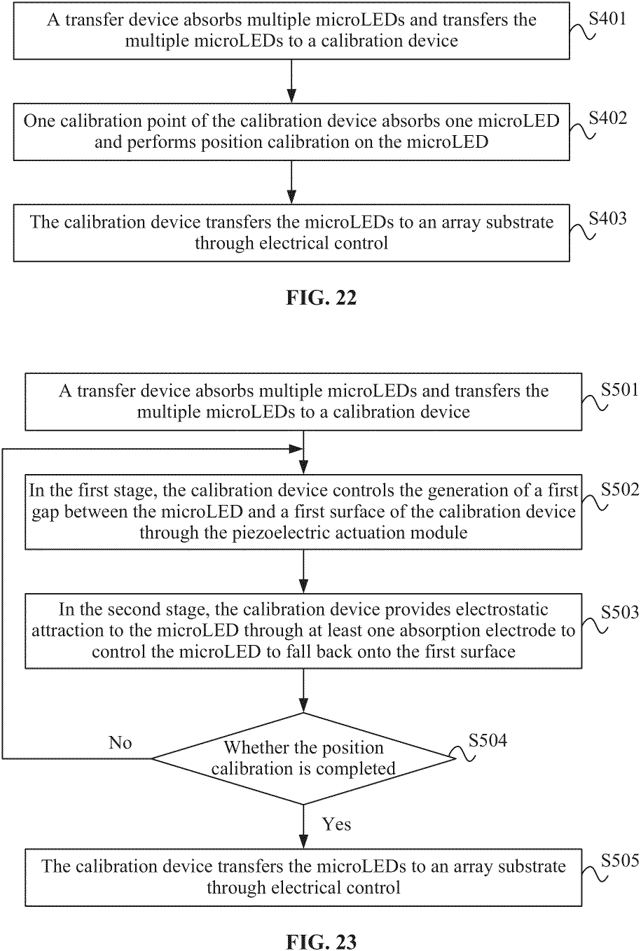

Based on the same inventive concept, the embodiment of the present disclosure further provides a mass transfer method performed by the mass transfer system provided in any of the preceding embodiments. Therefore, the mass transfer method has the same beneficial effects as the mass transfer system, the structure and the specific transfer principle of each transfer device in the mass transfer system may be understood in conjunction with the preceding embodiments, and the details are not repeated here. For example, FIG. 22 is a flowchart of a mass transfer method according to an embodiment of the present disclosure. As shown in FIG. 22, the mass transfer method includes the steps described below.

In S401, a transfer device absorbs multiple microLEDs and transfers the multiple microLEDs to a calibration device.

Optionally, the transfer device may be any one of a laser transfer device commonly used in the selective release technology, a transfer device that is based on the electrostatic force/Van der Waals force/magnetic force and commonly used in the accurate grasping technology, or a transfer device commonly used in the transfer printing technology, which is not limited in the embodiment of the present disclosure. The transfer device may pick up the microLEDs from the wafer or other substrates and transfer the microLEDs to the calibration device.

In S402, one calibration point of the calibration device absorbs one microLED and performs position calibration on the microLED.

For example, the calibration device can provide a certain absorption force, such as the electrostatic force or magnetic force, to the microLEDs through the calibration points, so as to absorb the microLEDs and calibrate the positions of the microLEDs. After the position calibration, the geometric center of the microLED nearly coincides with the geometric center of the calibration point.

In S403, the calibration device transfers the microLEDs to an array substrate through electrical control.

Specifically, the layout of the calibration points on the calibration device is related to the layout of the points (receiving points for short) on the array substrate for receiving the microLEDs. The calibration device is moved such that the calibration points are aligned with the corresponding receiving points, and the microLEDs are in contact with the array substrate. Then, the micro LEDs may be separated from the calibration device through electrical control, so as to transfer the microLEDs to the array substrate. For example, the electrical control method may specifically be to remove the absorption force of the calibration point on the microLED.

Further, after the microLEDs are transferred to the array substrate, the bonding metal may be melted by laser ablation or other methods to achieve the electrical connection between the microLEDs and pixel driving circuits in the array substrate, which is not limited in the embodiment of the present disclosure.

To sum up, in the embodiment of the present disclosure, when the microLEDs are transferred, the transfer device transfers the microLEDs to the calibration device, and the calibration points on the calibration device absorb the microLEDs and perform the position calibration on the microLEDs, thereby improving the transfer yield. At the same time, since the microLEDs are transferred from the calibration device to the array substrate through electrical control without hot pressing, a larger-sized calibration device can be manufactured so that more microLEDs can be transferred at one time and the position calibration can be performed on more microLEDs at one time, thereby ensuring a relatively high transfer rate.

FIG. 23 is a flowchart of another mass transfer method according to an embodiment of the present disclosure. Based on the preceding embodiment, the position calibration process of the microLEDs is further refined. As shown in FIG. 23, in this embodiment, the mass transfer method may include the steps described below.

In S501, a transfer device absorbs multiple microLEDs and transfers the multiple microLEDs to a calibration device.

After the microLEDs are transferred to the calibration device, one calibration point on the calibration device may absorb one microLED and perform position calibration on the microLED. Referring to FIG. 6, optionally, the calibration device 2 further includes the substrate 22 and the piezoelectric actuation module 23 located on the substrate 22, each calibration point 21 includes at least one absorption electrode 211, and the at least one absorption electrode 211 is located on a side of the piezoelectric actuation module 23 facing away from the substrate 22. Based on the calibration device, the position calibration process may include at least one calibration cycle, and one calibration cycle includes the first stage (S502 described below) and the second stage (S503) performed in sequence.

In S502, in the first stage, the calibration device controls the generation of a first gap between the microLED and a first surface of the calibration device through the piezoelectric actuation module.

The first surface is located on a side of the at least one absorption electrode facing away from the substrate. As shown in FIG. 7 (c), the generation of the first gap H1 between the microLED 200 and the first surface S1 of the calibration device 2 is controlled through the piezoelectric actuation module 23 so that the condition for the microLED to fall again may be created. Further, in the second stage, that is, during the falling process of the microLED 200, the microLED 200 moves toward the center of the calibration point by using the electrostatic attraction F provided by the at least one absorption electrode 211, so as to perform a certain degree of position calibration.

Optionally, the first stage includes the first process and the second process performed in sequence. The step in which the calibration device controls the generation of the first gap between the microLED and the first surface of the calibration device through the piezoelectric actuation module (S502) may include the following steps: in the first process, controlling, by the calibration device, the piezoelectric actuation module to expand from an initial state to a first state along a first direction within a first duration, where the first direction is perpendicular to a plane where the substrate is located; and in the second process, controlling, by the calibration device, the piezoelectric actuation module to contract from the first state to the initial state along the first direction within a second duration so that the first gap is formed between the microLED and the first surface. The first duration is at least ten times the second duration.

Specifically, in this embodiment, the piezoelectric actuation module is controlled to slowly expand and then rapidly contract so that the first gap can be generated between the microLED and the first surface of the calibration device due to inertia. The specific principle and explanation may be understood with reference to the relevant embodiments of FIGS. 8 and 9, and the details are not repeated here.

Optionally, the first duration is 10 µs to 100 µs, and the second duration is less than 1 µs.

In S503, in the second stage, the calibration device provides electrostatic attraction to the microLED through the at least one absorption electrode to control the microLED to fall back onto the first surface.

Specifically, the direction of the electrostatic attraction is directed from the geometric center of the microLED to the geometric center of the calibration point so that in the second stage, the microLED can move toward the center of the calibration point under the action of the electrostatic attraction, so as to perform a certain degree of position calibration. Multiple calibration cycles are repeated so that multiple position calibrations can be performed, thereby improving the position calibration accuracy and improving the transfer yield.

In S504, whether the position calibration is completed is determined, where if the position calibration is completed, S505 is performed; and if the position calibration is not completed, S502 is performed.

Specifically, after one or multiple calibration cycles, the calibration result may be detected. For example, whether the geometric center of the microLED coincides with the geometric center of the calibration point may be determined through manual observation with a microscope, so as to determine whether the position calibration is completed. If the position calibration is not completed, the next calibration cycle starts; and if the position calibration is completed, S505 is performed.

In S505, the calibration device transfers the microLEDs to an array substrate through electrical control.

In addition to removing the absorption force of the calibration point on the microLED to separate the microLED from the calibration device and transferring the calibration device to the array substrate, optionally, the step in which the calibration device transfers the microLEDs to the array substrate through electrical control (S505) may be performed through the steps described below.

The calibration device is moved until the microLEDs are in contact with the array substrate.

The calibration device controls the generation of a third gap between the microLEDs and the first surface of the calibration device through the piezoelectric actuation module to transfer the microLEDs to the array substrate.

Specifically, this method is similar to the principle of generating the first gap between the microLED and the first surface of the calibration device in S502. For example, through the principle of inertia, the piezoelectric actuation module rapidly contracts to control the generation of the third gap between the microLEDs and the first surface of the calibration device so that the microLEDs are separated from the calibration device, thereby transferring the microLEDs to the array substrate. If the microLEDs are separated from the calibration device by removing the electrostatic force of the calibration points on the microLEDs, there may be a possibility that the microLEDs are absorbed on the first surface of the calibration device due to the residual polarized charges, resulting in release failure. Moreover, even if this part of the microLEDs fall from the calibration device to the transfer device quickly, a certain distance exists between the dropped microLEDs and the receiving points since the calibration device is far away from the array substrate, resulting in an offset of the release position and affecting the transfer yield. In contrast, in this embodiment, the generation of the third gap between the microLEDs and the first surface of the calibration device is controlled through the piezoelectric actuation module, so as to achieve the release of the microLEDs and ensure that the microLEDs are always in contact with the array substrate, thereby ensuring the transfer yield.

It is to be noted that, in this embodiment, the case where the microLEDs are controlled to be in direct contact with the array substrate and controlled to be separated from the calibration device is used as an example for illustration. In other embodiments, a small gap may exist between the microLEDs and the array substrate, and the small gap has little impact on the transfer yield.

Additionally, it is to be noted that no size relationship exists between the third gap and the first gap, and those skilled in the art can design the size of the third gap by themselves, as long as the microLEDs are separated from the calibration device.

Additionally, it is to be noted that during the process of the calibration device controlling the generation of the third gap between the microLEDs and the first surface of the calibration device through the piezoelectric actuation module, the electrostatic attraction of the calibration points to the microLEDs may always be maintained or may be removed after the microLEDs are in contact with the array substrate (or a small gap exists between the microLEDs and the array substrate), which is not limited in the embodiment of the present disclosure.

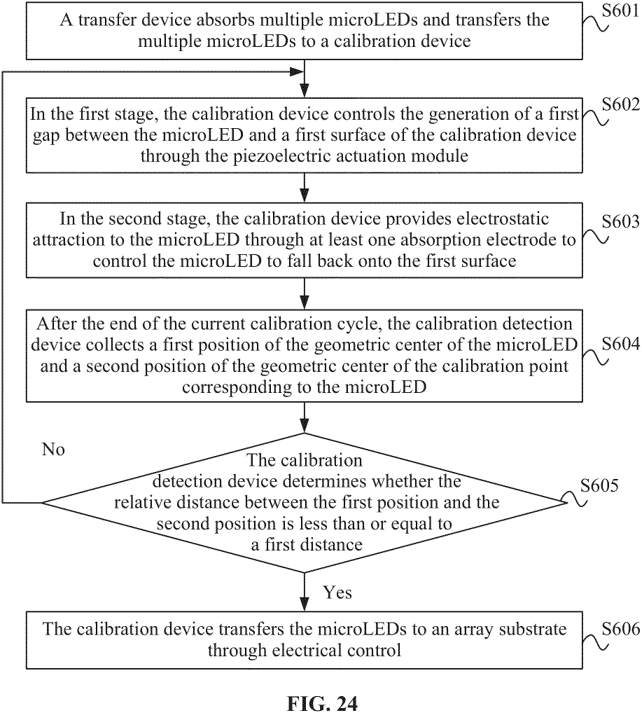

FIG. 24 is a flowchart of another mass transfer method according to an embodiment of the present disclosure. Based on the preceding embodiment, how to determine whether the position calibration is completed is further refined. Optionally, the mass transfer system further includes the calibration detection device. While the position calibration is performed on the microLEDs, the calibration detection device may determine whether the position calibration is completed. Specifically, as shown in FIG. 24, in this embodiment, the mass transfer method may include the steps described below.

In S601, a transfer device absorbs multiple microLEDs and transfers the multiple microLEDs to a calibration device.

In S602, in the first stage, the calibration device controls the generation of a first gap between the microLED and a first surface of the calibration device through the piezoelectric actuation module.

In S603, in the second stage, the calibration device provides electrostatic attraction to the microLED through at least one absorption electrode to control the microLED to fall back onto the first surface.

In S604, after the end of the current calibration cycle, the calibration detection device collects a first position of the geometric center of the microLED and a second position of the geometric center of the calibration point corresponding to the microLED.

In S605, the calibration detection device determines whether the relative distance between the first position and the second position is less than or equal to a first distance, where if the relative distance is less than or equal to the first distance, the position calibration is ended and S606 is performed; and if the relative distance is greater than the first distance, S602 is performed.

The first distance may be zero or a value very close to zero, which is not limited in the embodiment of the present disclosure. The calibration detection device may be an image sensor or another instrument capable of collecting object positions and having a certain data analysis capability, which is not limited in the embodiment of the present disclosure. Compared with the manual observation method, this detection method has higher accuracy and efficiency and can improve the transfer rate and transfer yield.

It is to be noted that the current calibration cycle may be any calibration cycle in the position calibration process. In FIG. 24, the case where the calibration detection device performs position collection and calibration result determination after each calibration cycle (S602 and S603) is used as an example for illustration. In other embodiments, the detection may be performed every several calibration cycles, which is not limited in the embodiment of the present disclosure.

In S606, the calibration device transfers the microLEDs to an array substrate through electrical control.

To sum up, in the mass transfer device and the mass transfer method provided in the embodiments of the present disclosure, during the transfer process, the calibration device performs position calibration on the microLEDs, and then the microLEDs are transferred from the calibration device to the array substrate through electrical control. At the same time, thanks to the use of electronic control to transfer the microLEDs from the calibration device to the array substrate, a large-sized calibration device can be manufactured so that the position calibration and transfer can be performed on more microLEDs at one time, the effect on the transfer rate can be reduced, and the mass transfer system can have both the relatively high transfer yield and the relatively high transfer rate.

The preceding embodiments do not limit the scope of the present disclosure. It is to be understood by those skilled in the art that various modifications, combinations, sub-combinations, and substitutions may be performed according to design requirements and other factors. Any modification, equivalent substitution, improvement, or the like made within the spirit and principle of the present disclosure is within the scope of the present disclosure.

What is claimed is:

1. A mass transfer system for transferring micro light-emitting diodes (microLEDs) to an array substrate, wherein the mass transfer system comprises a transfer device and a calibration device;
wherein the transfer device is configured to absorb a plurality of microLEDs and transfer the microLEDs to the calibration device;
the calibration device comprises a plurality of calibration points, wherein one calibration point of the calibration points is configured to absorb one microLED of the microLEDs and perform position calibration on the microLED; and
the calibration device is further configured to transfer the microLEDs to the array substrate through electrical control.

2. The mass transfer system of claim 1, wherein the calibration device further comprises a substrate and a piezoelectric actuation module located on the substrate, a calibration point of the calibration points comprises at least one absorption electrode, and the at least one absorption electrode is located on a side of the piezoelectric actuation module facing away from the substrate;
wherein a process of position calibration comprises at least one calibration cycle, and one calibration cycle of the at least one calibration cycle comprises a first stage and a second stage performed in sequence; in the first stage, the calibration device is configured to control generation of a first gap between the microLED and a first surface of the calibration device through the piezoelectric actuation module; in the second stage, the calibration device is configured to provide electrostatic attraction to the microLED through the at least one absorption electrode to control the microLED to fall back onto the first surface; and the first surface is located on a side of the at least one absorption electrode facing away from the substrate.

3. The mass transfer system of claim 2, wherein the first stage comprises a first process and a second process performed in sequence;
wherein in the first process, the calibration device is configured to control the piezoelectric actuation module to expand from an initial state to a first state along a first direction within a first duration, wherein the first direction is perpendicular to a plane where the substrate is located; and
in the second process, the calibration device is configured to control the piezoelectric actuation module to contract from the first state to the initial state along the first direction within a second duration so that the first gap is formed between the microLED and the first surface;
wherein the first duration is at least ten times the second duration.

4. The mass transfer system of claim 3, wherein the first duration is 10 µs to 100 µs, and the second duration is less than 1 µs.

5. The mass transfer system of claim 2, wherein the piezoelectric actuation module comprises a plurality of piezoelectric actuation units and a second gap exists between two adjacent piezoelectric actuation units of the plurality of piezoelectric actuation units.

6. The mass transfer system of claim 5, wherein a dimension of an orthographic projection of the transfer device on the substrate is less than or equal to a dimension of an orthographic projection of one piezoelectric actuation unit of the plurality of piezoelectric actuation units on the substrate.

7. The mass transfer system of claim 2, wherein the piezoelectric actuation module comprises a bottom electrode layer, a top electrode layer, and a piezoelectric material layer between the bottom electrode layer and the top electrode layer, wherein the top electrode layer is located on a side of the bottom electrode layer facing away from the substrate; and
the piezoelectric material layer comprises a plurality of piezoelectric units, and an insulating bank is provided between two adjacent piezoelectric units of the plurality of piezoelectric units.

8. The mass transfer system of claim 2, wherein the at least one absorption electrode comprises at least one first electrode and at least one second electrode, wherein a number of the at least one first electrode is equal to a number of the at least one second electrode, and a polarity of a voltage applied to the at least one first electrode and a polarity of a voltage applied to the at least one second electrode are opposite.

9. The mass transfer system of claim 8, wherein the at least one absorption electrode comprises at least two first electrodes and at least two second electrodes;
wherein along a second direction, the at least two first electrodes and the at least two second electrodes are arranged alternately; and/or along a third direction, the at least two first electrodes and the at least two second electrodes are arranged alternately; wherein the second direction and the third direction intersect and are parallel to a plane where the substrate is located.

10. The mass transfer system of claim 1, wherein an area of an orthographic projection of the microLED on the calibration device is greater than an area of a region where the calibration point is located.

11. The mass transfer system of claim 1, wherein the array substrate comprises a plurality of receiving units arranged in one-to-one correspondence with a plurality of sub-pixels; and
a number of the calibration points per unit area is greater than or equal to a number of the receiving units per unit area.

12. The mass transfer system of claim 11, wherein one receiving unit of the receiving units comprises one receiving point for receiving one microLED of the microLEDs; and
the number of the calibration points per unit area is N times a number of receiving points per unit area, wherein N is a positive integer.

13. The mass transfer system of claim 11, wherein the receiving unit comprises a first receiving point and a second receiving point, wherein at least one of the first receiving point or the second receiving point is configured to receive the microLED of the microLEDs; and
the calibration points comprise a plurality of first calibration points and a plurality of second calibration points, wherein one first calibration point of the first calibration points is provided corresponding to the first receiving point, and one second calibration point of the second calibration points is provided corresponding to the second receiving point.

14. The mass transfer system of claim 1, further comprising a calibration detection device, wherein the calibration detection device is configured to collect a first position of a geometric center of the microLED and a second position of a geometric center of the calibration point corresponding to the microLED and determine a position calibration result according to a relative distance between the first position and the second position.

15. A mass transfer method performed by a mass transfer system, wherein the mass transfer system comprises a transfer device and a calibration device;
wherein the transfer device is configured to absorb a plurality of micro light-emitting diodes (microLEDs) and transfer the plurality of microLEDs to the calibration device; the calibration device comprises a plurality of calibration points, wherein one calibration point of the calibration points is configured to absorb one microLED of the microLEDs and perform position calibration on the microLED; and the calibration device is further configured to transfer the microLEDs to the array substrate through electrical control;
wherein the mass transfer method comprises:
absorbing, by the transfer device, the plurality of microLEDs and transferring the plurality of microLEDs to the calibration device;
absorbing, by the calibration point of the calibration device, the microLED of the microLEDs and performing position calibration on the microLED of the microLEDs; and
transferring, by the calibration device, the microLEDs to the array substrate through electrical control.

16. The mass transfer method of claim 15, wherein the calibration device further comprises a substrate and a piezoelectric actuation module located on the substrate, a calibration point of the calibration points comprises at least one absorption electrode, and the at least one absorption electrode is located on a side of the piezoelectric actuation module facing away from the substrate; and
a process of position calibration comprises at least one calibration cycle, and one calibration cycle of the at least one calibration cycle comprises a first stage and a second stage performed in sequence; wherein performing the position calibration on the microLED of the microLEDs comprises:
in the first stage, controlling, by the calibration device, generation of a first gap between the microLED and a first surface of the calibration device through the piezoelectric actuation module; and
in the second stage, providing, by the calibration device, electrostatic attraction to the microLED through the at least one absorption electrode to control the microLED to fall back onto the first surface;
wherein the first surface is located on a side of the at least one absorption electrode facing away from the substrate.

17. The mass transfer method of claim 16, wherein the first stage comprises a first process and a second process performed in sequence; and controlling, by the calibration device, the generation of the first gap between the microLED and the first surface of the calibration device through the piezoelectric actuation module comprises:
in the first process, controlling, by the calibration device, the piezoelectric actuation module to expand from an initial state to a first state along a first direction within a first duration, wherein
the first direction is perpendicular to a plane where the substrate is located; and
in the second process, controlling, by the calibration device, the piezoelectric actuation module to contract from the first state to the initial state along the first direction within a second duration so that the first gap is formed between the microLED and the first surface;
wherein the first duration is at least ten times the second duration.

18. The mass transfer method of claim 17, wherein the first duration is 10 µs to 100 µs, and the second duration is less than 1 µs.

19. The mass transfer method of claim 16, wherein the mass transfer system further comprises a calibration detection device; and the mass transfer method further comprises:
after an end of a current one calibration cycle of the at least one calibration cycle, collecting, by the calibration detection device, a first position of a geometric center of the microLED of the microLEDs and a second position of a geometric center of the calibration point corresponding to the microLED of the microLEDs;
determining, by the calibration detection device, whether a relative distance between the first position and the second position is less than or equal to a first distance; and
in response to determining that the relative distance is less than or equal to the first distance, ending the position calibration, and in response to determining that the relative distance is greater than the first distance, entering a next one calibration cycle of the at least one calibration cycle.

20. The mass transfer method of claim 16, wherein transferring, by the calibration device, the microLEDs to the array substrate through the electrical control comprises:
moving the calibration device until the microLEDs are in contact with the array substrate; and
controlling, by the calibration device, generation of a third gap between the microLEDs and the first surface of the calibration device through the piezoelectric actuation module to transfer the microLEDs to the array substrate.
